(19) United States
(12) Patent Application Publication
(10) Pub. No.: US 2022/0295642 A1
(43) Pub. Date: Sep. 15, 2022

(54) Electronic Control Device

(71) Applicant: Hitachi Astemo, Ltd., Hitachinaka-shi, Ibaraki (JP)

(72) Inventors: Osamu IKEDA, Tokyo (JP); Shiro YAMASHITA, Hitachinaka-shi (JP)

(21) Appl. No.: 17/632,931

(22) PCT Filed: May 11, 2020
(86) PCT No.: PCT/JP2020/018881

§ 371 Date: Feb. 4, 2022

(30) Foreign Application Priority Data
Aug. 5, 2019 (JP) 2019-144061

(51) Int. Cl. H05K 3/34; H01L 23/12; B23K 35/26

(52) U.S. Cl. CPC H05K 3/3463; H01L 23/12; B23K 35/262; H05K 2201/10636; B23K 35/0244

(57) ABSTRACT

An electronic control device includes: a circuit board; an electronic component; and a bonding portion bonding the circuit board and the electronic component to each other. The bonding portion contains Sn as a main component, Bi and Sb in a total content ratio of 3 wt % or more, and Ag in a content of 3 to 3.9 wt %, with no In.

### TECHNICAL FIELD

The present invention relates to an electronic control device.

### BACKGROUND ART

The use of lead included in electronic control devices mounted on automobiles is regulated according to the RoHS directives and the ELV directives. Accordingly, non-use of lead has been promoted by lead-free solder mainly as Sn—3Ag—0.5Cu (wt %). In order to improve bondability in a bonding portion formed by solder, a method of adding an additive element to the solder has been studied. PTL 1 discloses a solder composition comprising a tin-silver-copper-based solder alloy and a metal oxide and/or a metal nitride, wherein the solder alloy consists of tin, silver, antimony, bismuth, copper, and nickel, with no germanium except germanium contained in impurities that are inevitably mixed, and with respect to the total amount of the solder composition, a content ratio of the silver is more than 1.0 mass % and less than 1.2 mass %, a content ratio of the antimony is 0.01 mass % or more and 10 mass % or less, a content ratio of the bismuth is 0.01 mass % or more and 3.0 mass % or less, a content ratio of the copper is 0.1 mass % or more and 1.5 mass % or less, a content ratio of the nickel is 0.01 mass % or more and 1.0 mass % or less, and a content ratio of the metal oxide and/or the metal nitride is more than 0 mass % and 1.0 mass % or less, with the balance of the tin.

### CITATION LIST

### Patent Literature

PTL 1: JP 2015 -20181 A

### SUMMARY OF INVENTION

### Technical Problem

In response to an increasing demand for electronization, EV, and electromechanical integration of automobiles, it may be increasingly required that in-vehicle electronic control devices be mounted on high-temperature portions around engines, motors, and the like. The inventors of the present invention have found that there is a possibility that sufficient bonding reliability may not be obtained in a bonding portion formed by conventional lead-free solder, such as Sn—3Ag—0.5Cu, in the above-described higher-temperature region due to its insufficient heat resistance. Furthermore, package components used for assembling the in-vehicle electronic control devices increasingly tend to use leadless components that are not gull-wing, which are widely used for mobile products, making it more difficult to obtain bonding reliability from the component shape. The invention described in PTL 1 has an effect against thermal fatigue fracture, but is not capable of suppressing void fracture that appears in a high-temperature region. Problems, configurations, and effects other than those described above will be apparent from the following description of embodiments for carrying out the invention.

### Solution to Problem

An electronic control device according to a first aspect of the present invention includes: a circuit board; an electronic component; and a bonding portion bonding the circuit board and the electronic component to each other, wherein the bonding portion contains Sn as a main component, Bi and Sb in a total content ratio of 3 wt % or more, and Ag in a content of 3 to 3.9 wt %, with no In.

### ADVANTAGEOUS EFFECTS OF INVENTION

According to the present invention, thermal fatigue fracture and void fracture can be suppressed.

### BRIEF DESCRIPTION OF DRAWINGS

FIG. 1 is a cross-sectional view of an electronic control device.

FIG. 2 is an enlarged view of a bonding portion.

FIG. 3 is a diagram for explaining a Bi and Sb content in a composition of the bonding portion.

FIG. 4 is a diagram for explaining an In content in the composition of the bonding portion.

FIG. 5 is a first diagram for explaining an Ag content in the composition of the bonding portion.

FIG. 6 is a second diagram for explaining an Ag content in the composition of the bonding portion.

FIG. 7 is a diagram for explaining a preferable Bi content in the composition of the bonding portion.

FIG. 8 is a diagram for explaining an experiment.

FIG. 9 is a diagram for explaining an experiment.

FIG. 10 is a diagram for explaining a preferable particle size of an intermetallic compound in the bonding portion.

FIG. 11 is a list of examples and comparative examples.

FIG. 12 is an enlarged view of a bonding portion according in a conventional configuration.

FIG. 13 is an X-ray photograph of the bonding portion in the conventional configuration.

### DESCRIPTION OF EMBODIMENTS

In the following embodiments, when a number concerning an element or the like (including a count, a numerical value, an amount, a range, or the like.) is mentioned, unless particularly specified or obviously limited to a specific number in principle, the number concerning the element is not limited to the specific number, and may be greater than or smaller than the specific number.

In addition, in the following embodiments, it goes without saying that a constituent elemental (including an elemental step or the like) is not necessarily essential, unless particularly specified or considered obviously essential in principle.

In addition, in the following embodiments, when an expression “including A”, “comprising A”, “having A”, or “containing A” is used for a constituent element or the like, it goes without saying that presence of other elements is not precluded, unless it is particularly specified that only the element is included. Likewise, in the following embodiments, when a shape, a positional relationship, or the like of a constituent element or the like is mentioned, it substantially includes one close or similar to the shape or the like, unless particularly specified or obviously considered so in principle. The same applies to the above-described numerical value, ranges, or the like.

Hereinafter, embodiments of the present invention will be described in detail with reference to the drawings. Note that, in all the drawings for describing the embodiments, members having the same functions are denoted by the same reference signs, and description thereof will not be repeated. In addition, hatching may be applied even to a plan view to make it easy to understand the drawings.

### Embodiment

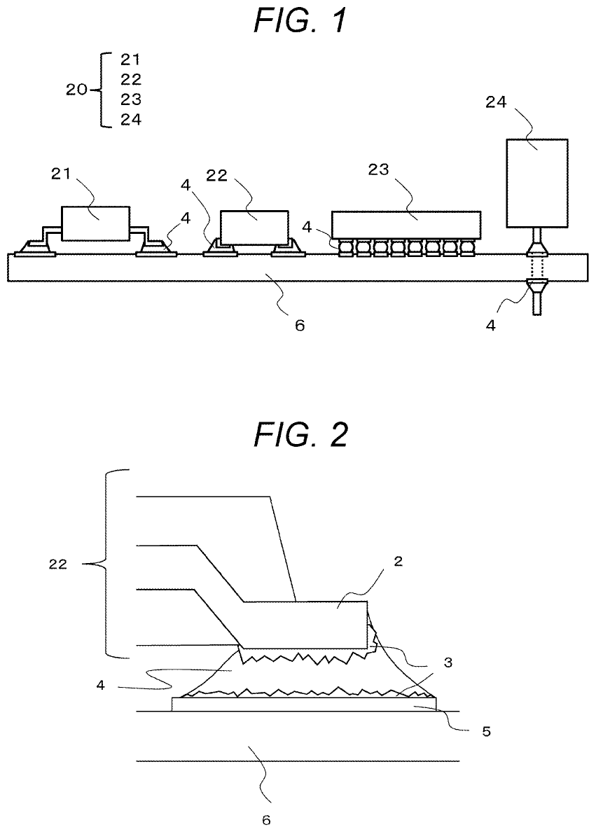

Hereinafter, an embodiment of an electronic control device will be described with reference to FIGS. 1 to 13. In the present embodiment, a composition ratio is expressed in mass %. Meanwhile, in experiments, wt % is accurate to two decimal places, and a composition of less than 0.01% is described as 0% because it is not measurable. In addition, mixing of inevitable impurities is allowed.

### Configuration

FIG. 1 is a cross-sectional view of an electronic control device 1 according to the present invention. The electronic control device 1 is an electronic control unit (ECU) mounted, for example, on a vehicle body or the like of an automobile. The electronic control device 1 may be configured in an electromechanically integrated manner. The electronic control device 1 includes a circuit board 6, a lead-attached component 21, a leadless component 22, a BGA component 23, and an insertion-mounted component 24. Hereinafter, the lead-attached component 21, the leadless component 22, the BGA component 23, and the insertion-mounted component 24 may also be collectively referred to as electronic components 20. A lead shape of the lead-attached component 21 is arbitrary, for example, gull-wing. The electronic component 20 is bonded to the circuit board 6 by a bonding portion 4.

FIG. 2 is an enlarged view of the bonding portion 4 on the leadless component 22. Each of the electronic components 20 has a Ni-plated terminal 2. An electrode 5 is disposed on a surface of the circuit board 6, and the bonding portion 4 and an intermetallic compound 3 are disposed between the electrode 5 and the terminal 2 of the leadless component 22. The bonding portion 4 contains tin (Sn) as a main component, Bi (bismuth) and Sb (antimony) in a total content ratio of 3 wt % or more, and silver (Ag) in a content of 3 to 3.9 wt % with no indium (In). The electrode 5 is any one of Cu, an alloy containing Cu as a main component, and a Cu plating. Hereinafter, the reason why the composition of the bonding portion 4 is as described above will be described.

### Experimental Value

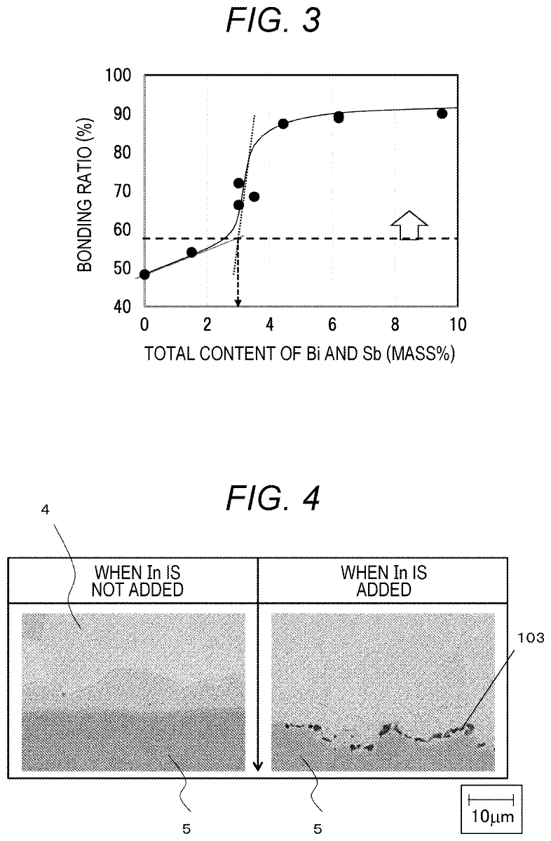

FIG. 3 is a diagram for explaining a Bi and Sb content in the composition of the bonding portion 4. The values shown in FIG. 3 are experimental values obtained through experiments by the inventors. In FIG. 3, the horizontal axis represents a total content of Bi and Sb in wt %, and the vertical axis represents a bonding ratio after a cycle test. The cycle test is a temperature cycle test in which an environmental temperature is changed alternately between −40° C. and 150° C. The test was performed with 1000 cycles to evaluate a bonding area ratio affected by crack development resulting from thermal fatigue fracture in the bonding portion 4. The higher the bonding ratio, that is, the closer to 100% the bonding ratio, the higher the thermal fatigue fracture resistance. The bonding ratio has an inflection point when the content ratio of Bi and Sb is 3 wt %, and thus, high reliability is obtained when the content ratio of Bi and Sb exceeds 3 wt %.

Note that both Bi and Sb are Group 15 elements, and similarly enter a crystal structure of Pb, which is a main component of the bonding portion 4. Therefore, it is only needed to evaluate a total amount of Bi and Sb, it is theoretically derived that the ratio between the two elements does not matter.

FIG. 4 is a diagram for explaining an In content in the composition of the bonding portion 4. The X-ray photographs shown in FIG. 4 are obtained through experiments by the inventors. FIG. 4 shows X-ray photographs indicating how addition of In affects the Sn—Cu-based bonding portion 4 when exposed to 200° C. for 1000 hours. In a case where In is added on the right side of the drawing, the reaction of the bonding portion 4 is promoted, and voids 103 are generated, thereby causing a deterioration at an interface of the bonding portion. On the other hand, In a case where In is not added on the left side of the drawing, no voids are generated. Therefore, it is not preferable to add In to the bonding portion 4.

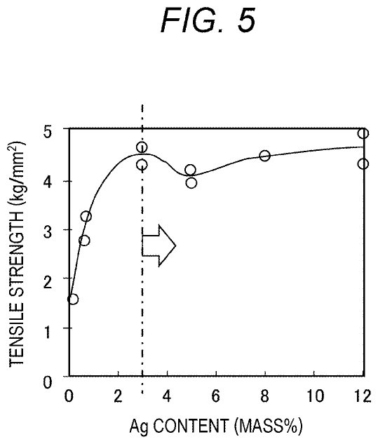

FIG. 5 is a first diagram for explaining an Ag content in the composition of the bonding portion 4. The diagram shown in FIG. 5 is obtained by appropriately editing the diagram presented in the article by Ishida et al. (Gu Ishida, Influence of Various Elements on Mechanical Properties and Corrosion Resistance of Tin, Journal of the Japan Society of Metals, vol. 8, no. 8, p. 389-396, 1944) for description. FIG. 5 is a diagram showing a relationship between an Ag content and a mechanical strength. As the Ag content increases from 0%, the tensile strength increases, reaches a peak when the Ag content is 3 wt %, and maintains a high level when the Ag content is 3 wt % or more.

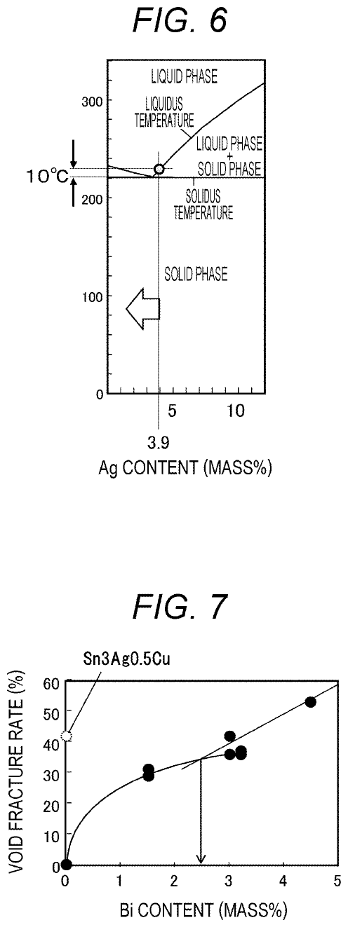

FIG. 6 is a second diagram for explaining an Ag content in the composition of the bonding portion 4. The drawing shown in FIG. 6 is obtained by appropriately editing the drawing presented in the literature (Thaddeus B. Massalski, Binary Alloy Phasediagram, p. 71) for description. FIG. 6 is a Sn—Ag binary phase diagram, in which the horizontal axis represents an Ag content and the vertical axis represents a Celsius temperature. For example, the left end of the horizontal axis indicates that the Ag content is zero, that is, the characteristics of Sn alone. The solidus temperature shown in FIG. 6 is a temperature at which solder starts to melt. The liquidus temperature shown in FIG. 6 is a temperature at which the solder is completely melted. When a temperature difference therebetween is large, it is likely that shrinkage cavities are generated in the bonding portion 4 during solidification shrinkage of the solder cooled after soldering. The generated shrinkage cavity may be a starting point of crack development resulting from thermal fatigue fracture, thereby causing a decrease in reliability of the bonding portion 4.

As shown in FIG. 6, the Ag content of 3.5% forms an eutectic point at 220 degrees, and an increase in Ag content causes a large difference between the solidus temperature and the liquidus temperature. In the present embodiment, a threshold value of the Ag content is 3.9%, in which a difference between the solidus temperature and the liquidus temperature is 10 degrees. When combined with the lower limit of the Ag content described with reference to FIG. 5, the Ag content is preferably in a range of 3% to 3.9%.

FIG. 7 is a diagram for explaining a preferable Bi content in the composition of the bonding portion 4. The diagram shown in FIG. 7 is obtained through experiments by the inventors. In FIG. 7, the horizontal axis represents a Bi content, and the vertical axis represents a void fracture rate based on a high-temperature creep test. In the high-temperature creep test, a load of 600 g was applied for 960 hours in an environment of 150 degrees. Note that, among the plots shown in FIG. 7, only the plot indicated by the white dotted line shown at the upper-left portion is a test result of Sn—3Ag—0.5Cu, which has been conventionally used.

As shown in FIG. 7, the void fracture rate tends to increase as the Bi content increases. The void fracture rate appears to be saturated once the Bi content reaches 2.5%, but the void fracture rate increases in proportion to the Bi content when the Bi content is 2.5 wt % or more. When the Bi content further increases, the void fracture rate becomes higher than that of Sn—3Ag—0.5Cu. Therefore, the Bi content of the bonding portion 4 is preferably less than 2.5 wt %.

The results of FIGS. 3 and 7 are as follows. First, the void fracture is caused by the cavities generated in the structural grain boundary, that is, creep voids, which result from deformation that proceeds due to the stress load on the grain boundary. The addition of Sb or Bi, which imparts creep deformability to the Sn-based solder bonding portion at a high temperature, is effective in generating creep voids for relaxing the stress at the grain boundary. This is illustrated in FIG. 3. However, as shown in FIG. 7, the addition of Bi has an adverse effect. This is because of segregation of Bi at the interface of the bonding portion. When Bi is segregated at the interface of the bonding portion, the Bi content locally increases, causing a decrease in melting point. When the melting point decreases, holes are introduced at a high concentration, thereby easily generating creep voids. Therefore, the void fracture can be greatly suppressed by not containing Bi in the solder.

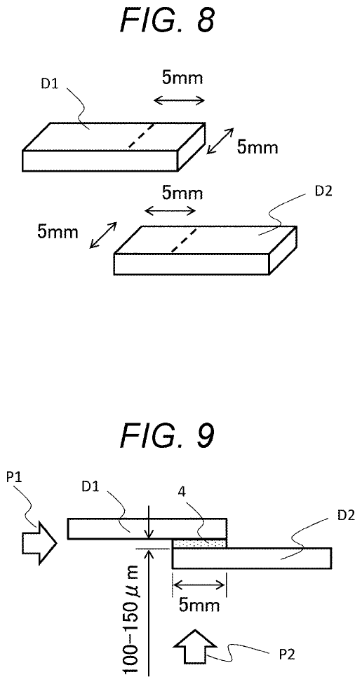

FIGS. 8 to 10 are diagrams for explaining a preferable particle size of the intermetallic compound in the bonding portion 4. FIGS. 8 and 9 are diagrams for explaining experiments. The diagram shown in FIG. 9 is obtained through experiments by the inventors. In each of these experiments, as shown in FIG. 8, two rectangular parallelepiped test pieces D1 and D2 having a width of 5 mm were used, and their end portions of 5 mm were bonded to each other by the bonding portion 4. The test pieces after being bonded are shown in FIG. 9. The bonding portion 4 has a thickness of 100 μm to 150 μm. In the depth direction of FIG. 9, the bonding portion 4 continues by 5 mm as shown in FIG. 8. Hereinafter, the bonding portion 4 will be evaluated, the bonding portion 4 having been photographed with an X-ray from a viewpoint P1 in the horizontal direction of the drawing and from a viewpoint P2 in the vertical direction of the drawing.

In these experiments, intermetallic compounds for bonding portions 4 were generated in four kinds of particle sizes by making adjustments in terms of bonding profile, maintenance at a high temperature after bonding, optimization of metallization of the members, and optimization of the solder composition used for soldering. Then, reliability tests in which a load of 600 g was applied in a shear direction at 150° C. were performed, and X-ray photographs of the bonding portions 4 taken at the viewpoint P1 and the viewpoint P2 after the tests were performed were compared. Note that the intermetallic compound in these experiments may be a Cu—Sn compound alone, a Ni—Sn compound alone, or a combination of the Cu—Sn compound and the Ni—Sn contained in an arbitrary ratio.

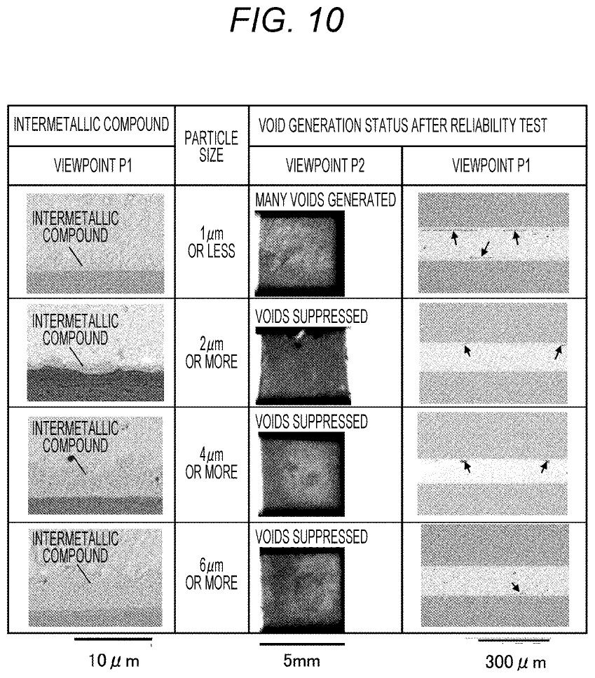

FIG. 10 is a diagram showing test results, and illustrates intermetallic compounds before the reliability tests are performed, particle sizes of the intermetallic compounds, and void generation statuses after the reliability tests are performed by generating four bonding portions 4. The intermetallic compound is an X-ray image obtained at the viewpoint P1, and the void generation status was checked through photographs taken at the viewpoint P1 and viewpoint P2, respectively. However, as illustrated in the lowermost portion of FIG. 10, scales are different from each other. In FIG. 10, the particle sizes increase in the downward direction of the drawing. In a case where the particle size is 1 μm or less as shown at the uppermost stage, many voids are observed. Note that, at the right end of FIG. 10, arrows are illustrated to clearly indicate the generated voids observed at the viewpoint P1.

In the experimental results shown in the second and subsequent stages of FIG. 10, in which the particle size is 2 μm or more, there is a void suppressing effect because voids are significantly reduced as compared with those at the uppermost stage, in which the particle size is less than 2 μm. When the particle size of the intermetallic compound is small, it is likely that stress concentration occurs, and voids are generated. In contrast, when the particle size of the intermetallic compound is large, it is less likely that stress concentration occurs, and the generation of voids is suppressed. In order to increase the particle size of the intermetallic compound, some measures are required, such as optimization of bonding profile, maintenance at a high temperature after bonding, optimization of metallization of the members, and optimization of the solder composition used for soldering. As a measure for the metallization of the members, a component having a Ni-plated terminal may be bonded to a circuit board with Cu, the terminal may be metallized with Ni/Cu plating, or the like. In addition, as a measure for the solder composition used for soldering, the Cu content may be increased to 1 wt % or more or the like.

Since the electrode 5 of the circuit board 6 is any one of Cu, an alloy containing Cu as a main component, and a Cu plating, and the terminal 2 of the electronic component 20 is Ni-plated, Cu of the electrode 5 is diffused into the solder during soldering and reacts with Sn, and a Cu—Sn compound and a Ni—Sn compound are generated. The coarse Cu—Sn and Ni—Sn compounds adhere onto the Ni plating of the terminal of the electronic component, thereby obtaining a coarse intermetallic compound, that is, an intermetallic compound having a large particle size.

### Examples

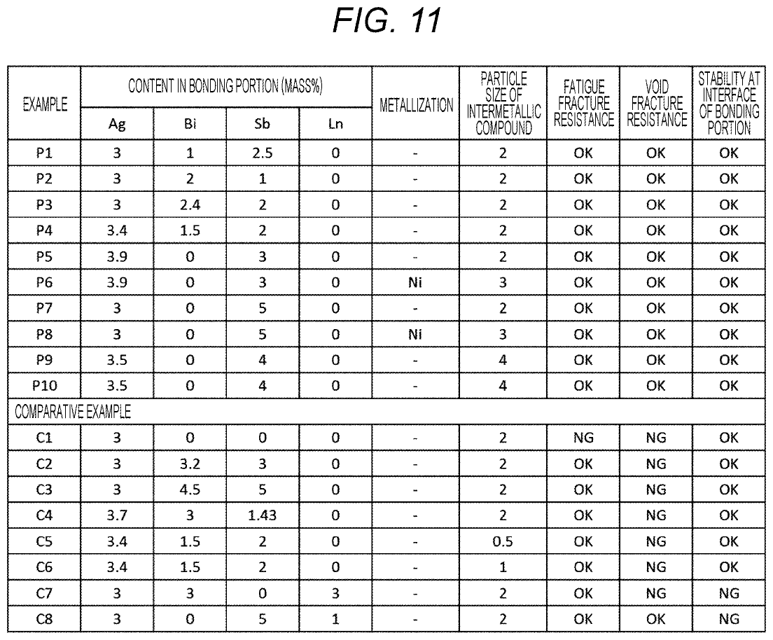

FIG. 11 is a list of examples and comparative examples. P1 to P10 illustrated in the upper half of FIG. 11 are examples, and C1 to C8 illustrated in the lower half of FIG. 11 are comparative examples. As shown in FIG. 11, the examples and the comparative examples are different from each other in an each element content in a bonding portion, whether or not there is metallization, and a particle size of an intermetallic compound. The metallization shown in FIG. 11 indicates whether or not the terminal of the component mounted is metallized, and “-” is written when no plating is performed, that is, for a pure state where copper is exposed, and “Ni” is written when nickel plating is performed. Note that, in all of the examples and the comparative examples, the circuit board is not metallized and is in a pure copper state. In addition, the unit of the each element content wt %, and the unit of the particle size of the intermetallic compound is pm. Meanwhile, wt % is accurate only to two decimal places. For example, even though 0% is described in some columns, the content may be less than 0.01%.

In three columns from the right end of FIG. 11, results of evaluating a fatigue fracture resistance, a void fracture resistance, and a stability at the interface of the bonding portion are shown. This evaluation is a comparison with a bonding portion based on Sn—3Ag—0.5Cu solder. In comparison with the reliability of the bonding portion based on the Sn—3Ag—0.5Cu solder, higher reliability was evaluated as “OK” and lower reliability was evaluated as “NG”.

In all of Examples P1 to P10, reliability was higher than that of the bonding portion based on the Sn—3Ag—0.5Cu solder. This results from the above-described effects. In Comparative Example C1, Bi and Sb were not added, and the thermal fatigue fracture resistance and the void fracture resistance were evaluated as NG. In Comparative Examples C2 to C6, the thermal fatigue fracture resistance was evaluated as “OK” since Bi and Sb were added, but the void fracture resistance was evaluated as “NG” since the Bi content was more than 2.5 wt % or the particle size of the intermetallic compound formed at the interface of the bonding portion was less than 2 μm. In Comparative Examples C7 and C8, since In was contained, the stability at the interface of the bonding portion was evaluated as “NG”.

According to the above-described embodiment, the following effects are obtained.

(1) An electronic control device 1 includes a circuit board 6, an electronic component 20, and a bonding portion 4 bonding the circuit board 6 and the electronic component 20 to each other. The bonding portion 4 contains Sn as a main component, Bi and Sb in a total content ratio of 3 wt % or more as shown in FIG. 3, and Ag in a content of 3 to 3.9 wt % as shown in FIGS. 5 and 6, with no In as shown in FIG. 4. Therefore, as shown in Examples P1 to P10 of FIG. 11, thermal fatigue fracture and void fracture can be suppressed.

(2) An Bi content of the bonding portion 4 is preferably less than 2.5 wt % as shown in FIG. 7. As shown in FIG. 10, an intermetallic compound formed at an interface between the electronic component 20 and the bonding portion 4 preferably has a particle size of 2 μm or more, and includes at least one of a Cu—Sn compound and a Ni—Sn compound. Therefore, since the Bi content is less than 2.5 wt %, an adverse effect on void fracture rate caused when Bi is contained is limited as shown in FIG. 7. Also, since the particle size is large, generation of voids is suppressed as shown in FIG. 10.

(3) The bonding portion 4 does not contain Bi. Therefore, as shown in FIG. 7, there is no adverse effect on void fracture rate caused when Bi is contained.

(4) An electrode 5 of the circuit board 4 is any one of Cu, an alloy containing Cu as a main component, and a Cu plating, and a terminal electrode of the electronic component 20 is Ni-plated. Therefore, during soldering, Cu of the circuit board is diffused into the solder and reacts with Sn, and a Cu—Sn compound and a Ni—Sn compound are generated, such that the particle size of the intermetallic compound increases, thereby suppressing generation of voids.

(5) One of the electronic components 20 is a leadless component 22, and the electronic control device 1 has an electromechanically integrated configuration. Therefore, even though the leadless component 22, in which problems of thermal fatigue fracture and void fracture are likely to occur, is mounted on the electronic control device 1, since the electronic control device 1 is configured in the electromechanically integrated manner, both the thermal fatigue fracture and the void fracture can be suppressed even in an environment where the electronic control device 1 is exposed to a high temperature, thereby obtaining high reliability.

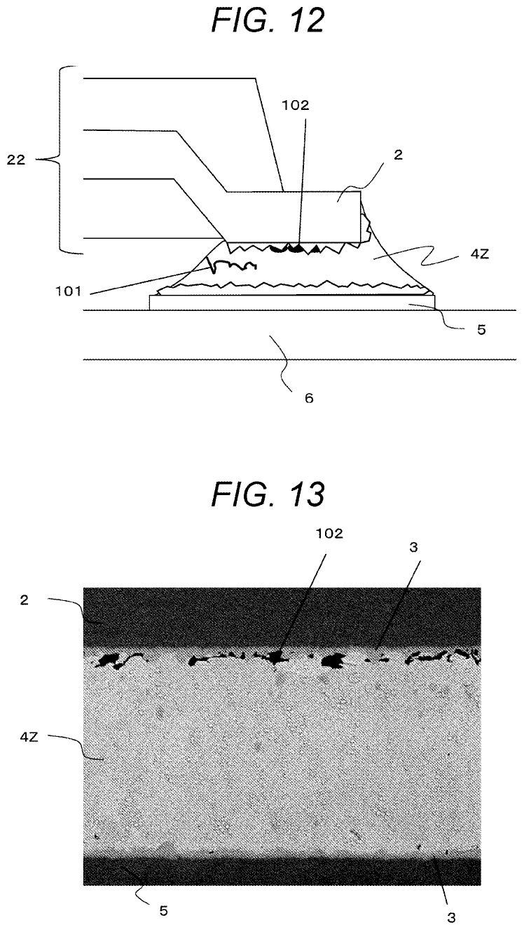

FIG. 12 is an enlarged view of a bonding portion 4Z using Sn—3Ag—0.5Cu on a leadless component 22. FIG. 13 is an X-ray photograph of the bonding portion 4Z using Sn—3Ag—0.5Cu on the leadless component 22. When Sn—3Ag—0.5Cu is used, thermal fatigue fracture and void fracture are likely to occur in the bonding portion 4Z on the leadless component 22. As shown in FIG. 12, the fatigue fracture is caused by a crack that develops from a solder fillet end of the bonding portion 4Z, and the void fracture is caused by a void generated near an interface of a terminal. As shown in FIG. 13, the void fracture is a fracture mode in which voids are continuously generated along the interface of the bonding portion on the terminal of the leadless component 22. The void fracture is a fracture mode that appears in the bonding portion 4Z on the leadless component 22 for a product used under relatively severe temperature conditions such as the electronic control device 1. In general, a solder bonding portion of an electronic control component has been designed so far for a lifespan of a product by predicting the lifespan using the Coffin-Manson's rule, while fatigue fracture is considered as a main fracture mode. However, the void fracture is different from the thermal fatigue fracture in terms of mechanism, and a lifespan affected thereby cannot be predicted using the Coffin-Manson's law. Therefore, the suppression of the void fracture using the method described in the present embodiment has great significance.

### Modification 1

The electronic control device 1 may include at least one of the lead-attached component 21, the leadless component 22, the BGA component 23, and the insertion-mounted component 24.

The above-described embodiments and modification may be combined together. Although the various embodiments and modification have been described above, the present invention is not limited thereto. Other aspects conceivable within the technical spirit of the present invention also fall within the scope of the present invention.

The disclosure of the following priority application is incorporated herein by reference.

Japanese Patent Application No. 2019 -144061 (filed on Aug. 5, 2019)

### REFERENCE SIGNS LIST

1 electronic control device

2 terminal

3 intermetallic compound

4 bonding portion

5 electrode

6 circuit board

22 leadless component

1. An electronic control device, comprising:
a circuit board;
an electronic component; and
a bonding portion bonding the circuit board and the electronic component to each other,
wherein the bonding portion contains Sn as a main component, Bi and Sb in a total content ratio of 3 wt % or more, and Ag in a content of 3 to 3.9 wt %, with no In.

2. The electronic control device according to claim 1, wherein
a Bi content of the bonding portion is less than 2.5 wt %, and
an intermetallic compound formed at an interface between the electronic component and the bonding portion has a particle size of 2 μm or more, and includes at least one of a Cu—Sn compound and a Ni—Sn compound.

3. The electronic control device according to claim 1, wherein the bonding portion does not contain Bi.

4. The electronic control device according to claim 1, wherein
an electrode of the circuit board is any one of Cu, an alloy containing Cu as a main component, and a Cu plating, and
a terminal electrode of the electronic component is Ni-plated.

5. The electronic control device according to claim 1, wherein
the electronic component is a leadless component, and
the electronic control device has an electromechanically integrated configuration.
